(19) United States
(12) Patent Application Publication
(10) Pub. No.: US 2014/0248504 A1
(43) Pub. Date: Sep. 4, 2014

(54) RESIN COMPOSITION, RESIN SHEET, CURED RESIN SHEET, RESIN-ADHERED METAL FOIL AND HEAT DISSIPATION DEVICE

(71) Applicants: Shihui Song, Tsukuba-shi (JP); Yukihiko Yamashita, Tsukuba-shi (JP); Yoshitaka Takezawa, Tsukuba-shi (JP); Hideyuki Katagi, Tsukuba-shi (JP)

(72) Inventors: Shihui Song, Tsukuba-shi (JP); Yukihiko Yamashita, Tsukuba-shi (JP); Yoshitaka Takezawa, Tsukuba-shi (JP); Hideyuki Katagi, Tsukuba-shi (JP)

(73) Assignee: HITACHI CHEMICAL COMPANY, LTD.

(21) Appl. No.: 14/343,375

(22) PCT Filed: Feb. 17, 2012
(86) PCT No.: PCT/JP2012/053879

§ 371 Date: May 20, 2014

(30) Foreign Application Priority Data
Sep. 8, 2011 (JP) 2011-196248

(51) Int. Cl. H01L 23/373

(52) U.S. Cl. CPC H01L 23/3737
USPC 428/469; 524/404

(57) ABSTRACT

The present invention provides a resin composition, including: a filler that includes alumina particles and boron nitride particles; an elastomer having a weight-average molecular weight of from 10,000 to 100,000; and a curable resin. The present invention also provides a resin sheet, a cured resin sheet, a resin-adhered metal foil and a heat dissipation device, which are formed by using the resin composition.

### TECHNICAL FIELD

The present invention relates to a resin composition, a resin sheet, a cured resin sheet, a resin-adhered metal foil, and a heat dissipation device.

### BACKGROUND ART

In the field of semiconductors such as a power transistor, a thermistor, a printed circuit board and an IC chip, and in other fields of electric and electronic components, a thermally conductive resin composition that includes an epoxy resin and an inorganic filler is widely used as a thermally conductive insulating material that constitutes a heat dissipation device.

A thermally conductive resin composition is required to have an excellent strength and an excellent thermal conductivity. In order to achieve both of a high strength and a high thermal conductivity, in many cases, a mixed filler of alumina (contributing to a high strength) and boron nitride (contributing to a high thermal conductivity) is used for the preparation of a thermally conductive resin composition. For example, a thermally conductive resin composition in which an epoxy resin is filled with a mixed filler of alumina and nitrogen compounds is disclosed (for example, see Japanese Patent Application Laid-Open (JP-A) No. 2001-348488).

However, since the viscosity of a resin composition including boron nitride tends to become high, a large number of voids (air bubbles) may be formed in the resin composition during kneading the materials. A resin sheet formed by application of a resin composition including voids may be inferior in insulation properties due to the existence of the voids.

In addition, in order to attain an effect of enhancing thermal conductivity by using boron nitride, a high-pressure pressing needs to be performed during preparation of a resin sheet. As a result, the formed resin sheet tends to be hard and less flexible, whereby its adhesive strength with respect to a metal substrate or the like may be low.

The reason why a resin composition including boron nitride is high in viscosity and requires high-pressure pressing are thought to be that boron nitride has a poor affinity with respect to an epoxy resin or the like, and wettability with respect to the epoxy resin is not sufficient.

In connection with this, treating a surface of boron nitride with an isocyanate compound has been proposed (for example, see JP-A No. 2001-192500).

Further, use of a compound having a nitroso group or an oxime group as an additive for improving the affinity between a boron nitride filler and a resin has been proposed (for example, see JP-A No. 2008-179720).

### SUMMARY OF THE INVENTION

### Problems to be Solved by the Invention

Boron nitride has less functional groups at its surface as compared with alumina. For this reason, there may be cases in which it is difficult to attain a sufficient improvement in the properties of materials including boron nitride by modifying a surface of boron nitride by the methods described in JP-A No. 2001-192500 and JP-A No. 2008-179720.

In view of the above, an object of the present invention is to provide a resin composition that is capable of forming a cured resin that has an excellent insulation and an excellent adhesion while having an excellent thermal conductivity; a resin sheet and a resin-adhered metal foil that are formed by using the resin composition and have an excellent flexibility; and a cured resin sheet and a heat dissipation device.

### Means for Solving the Problems

Specific means for solving the problems are as follows.

<1> A resin composition, comprising: a filler that includes alumina particles and boron nitride particles; an elastomer having a weight-average molecular weight of from 10,000 to 100,000; and a curable resin.

<2> The resin composition according to <1>, wherein the elastomer has a polarizable functional group.

<3> The resin composition according to <2>, wherein the functional group is at least one selected from the group consisting of an ester group, a carboxy group and a hydroxy group.

<4> The resin composition according to any one of <1> to <3>, wherein the weight-average molecular weight of the elastomer is from 10,000 to 50,000.

<5> The resin composition according to any one of <1> to <4>, wherein the content ratio of the alumina particles and the boron nitride particles in the filler (alumina particles:boron nitride particles) is 20 mass % to 80 mass %:80 mass % to 20 mass %.

<6> A resin sheet that is a product formed by molding the resin composition according to any one of <1> to <5> in a sheet shape.

<7> A cured resin sheet that is a cured product of the resin sheet according to <6>.

<8> A heat dissipation device, comprising: a metal work; and the resin sheet according to <6> or the cured resin sheet according to <7>, which is disposed on the metal work.

<9> A resin-adhered metal foil, comprising: a metal foil; and a resin composition layer that is a coating of the resin composition according to any one of <1> to <5>, disposed on the metal foil.

### Effect of the Invention

According to the present invention, it is possible to provide a resin composition that is capable of forming a cured resin that has an excellent insulation property and an excellent adhesion while having an excellent thermal conductivity; a resin sheet and a resin-adhered metal foil that are formed by using the resin composition and have an excellent flexibility; and a cured resin sheet and a heat dissipation device.

### BRIEF DESCRIPTION OF DRAWINGS

FIG. 1 is a schematic cross section illustrating one example of a heat dissipation device related to the present embodiment.

FIG. 2a is a schematic cross section illustrating a state in which the resin sheet has a poor flexibility in the judgment of flexibility performed in the Examples.

FIG. 2b is a schematic cross section illustrating a state in which the resin sheet has a favorable flexibility in the judgment of flexibility performed in the Examples.

### DESCRIPTION OF EMBODIMENTS

As used herein, the term “process” includes not only an independent process but also a process that cannot be clearly separated from another process, provided that the intended action of the process is achieved. The numerical range represented by “A to B” refers to a range including A and B as the minimum value and the maximum value, respectively. Further, when there are plural substances that correspond to one component, the amount of the component in a composition refers to the total amount of the plural substances in the composition, unless otherwise specified.

<Resin Composition>

The resin composition of the invention includes: a filler including at least one kind of alumina particles and at least one kind of boron nitride particles; at least one kind of curable resin; and at least one kind of elastomer having a weight-average molecular weight of from 10,000 to 100,000. The resin composition may further include other components, as needed.

By including an elastomer having a specified weight-average molecular weight in the resin composition, an increase in viscosity can be suppressed. Further, a cured resin having an excellent insulation and an excellent adhesion while having an excellent thermal conductivity can be formed. In addition, a resin sheet formed by using the resin composition has an excellent flexibility.

The reason for this can be thought, for example, as follows. When an elastomer has a specified molecular weight, the elastomer can be efficiently adsorbed, for example, to surfaces of alumina particles constituting a filler, thereby improving the dispersibility of the alumina particles in a curable resin. As a result, aggregation of a filler containing alumina particles and boron nitride particles is suppressedm and the viscosity of a resin composition is reduced and the generation of voids in a resin composition is suppressed, whereby insulation is improved. Further, by including an elastomer having a low elasticity in the resin composition, elasticity of the whole resin composition decreases. As a result, an effect of stress relaxation is obtained upon attachment to an adherend such as a metal, thereby further improving the adhesion.

[Filler]

The filler in the resin composition includes at least one kind of alumina particles and at least one kind of boron nitride particles. The filler may include a filler of a different kind, as needed. By including both alumina particles and boron nitride particles in the filler, a cured object having an excellent thermal conductivity and an excellent adhesive strength can be formed.

(Alumina Particles)

The alumina particles are not particularly restricted, and alumina particles commonly used in the present industrial field may be selected and used. Examples of alumina that constitutes the alumina particles include α-alumina, γ-alumina, θ-alumina and δ-alumina. From the viewpoint of chemical stability and interaction with an elastomer, alumina particles including α-alumina are preferable, and from the viewpoint of being uniform in shape, having a narrow particle size distribution and having a high purity, alumina particles composed of single crystal α-alumina are more preferable.

The alumina particles may be selected from commercially available products, or may be prepared as desired by performing a heat treatment, a crushing treatment or the like.

The particle size of the alumina particles is not particularly restricted. For example, alumina particles having an average particle size of from 0.01 μm to 100 μm may be used. From the viewpoint of suppressing aggregation, the average particle size of the alumina particles is preferably from 0.4 μm to 100 μm. From the viewpoint of improving handling property, the average particle size of the alumina particles is more preferably 0.4 μm to 50 μm. From the viewpoint of attaining a high thermal conductivity, the average particle size of the alumina particles is particularly preferably from 0.4 μm to 20 μm.

The alumina particles may be alumina particles that have a particle size distribution with a single peak, or may be a combination of alumina particles of plural kinds having different particle size distributions. From the viewpoint of filling ability as a filler, the alumina particles are preferably a combination of two or more kinds of alumina particles having different particle size distributions, more preferably a combination of three or more kinds of alumina particles having different particle size distributions.

When the alumina particles are a combination of plural kinds of alumina particles, the mixing ratio thereof may be selected depending on the number of kinds of alumina particles to be combined, the average particle size of the alumina particles, and the like.

For example, in a case of using three kinds of alumina particles having different particle size distributions, a suitable combination of alumina particles include (A) alumina particles having an average particle size of from 10 μm to 100 μm, (B) alumina particles having an average particle size of from 1 μm to less than 10 μm and (C) alumina particles having an average particle size of from 0.01 μm to less than 1 μm, wherein the ratios of alumina particles (A), (B) and (C) with respect to the total volume of the alumina particles are from 55 vol % to 85 vol %, from 10 vol % to 30 vol %, and from 5 vol % to 15 vol %, respectively, provided that the total of the alumina particles (A), (B) and (C) is 100 vol %.

For example, in a case of using two kinds of alumina particles having different particle size distributions, a suitable combination of alumina particles include (A1) alumina particles having an average particle size of from 1 μm to 10 μm and (B1) alumina particles having an average particle size of from 0.01 μm to less than 1 μm, wherein the ratios of alumina particles (A1) and (B1) with respect to the total volume of the alumina particles are from 55 vol % to 85 vol % and from 15 vol % to 45 vol %, respectively, provided that the total of the alumina particles (A1) and (B1) is 100 vol %. In a more suitable combination, the ratios of alumina particles (A1) and (B1) with respect to the total volume of the alumina particles are from 65 vol % to 75 vol % and from 25 vol % to 35 vol %, respectively, provided that the total of the alumina particles (A1) and (B1) is 100 vol %.

The average particle size of the alumina particles is measured as a volume average particle size with a laser diffraction scattering-type particle size distribution analyzer by a wet method. The particle size distribution of the alumina particles can be measured by a laser diffraction scattering method. In a case of a laser diffraction scattering method, the measurement can be performed by extracting a filler from a resin composition or a resin sheet (including a cured product thereof) and carrying out the measurement for the extracted filler with a laser diffraction scattering-type particle size distribution analyzer (for example, LS230 manufactured by Beckman Coulter Inc.) Specifically, a filler component is extracted from a resin composition or a resin sheet by using an organic solvent, nitric acid, aqua regia or the like, and sufficiently dispersing the extracted filler component with an ultrasonic disperser or the like. By measuring the particle size distribution of the dispersion, the particle size distribution of the filler can be measured. By calculating the volume of the particle groups corresponding to each peak in the particle size distribution of the filler, the volume content of the particle groups corresponding to each peak in the total volume of the filler can be calculated. Whether or not the filler is alumina particles can be determined by measuring an X-ray diffraction spectrum (XRD) of the filler corresponding to each peak.

(Boron Nitride Particles)

The boron nitride particle is not particularly limited, and may be selected from boron nitride particles commonly used in the present industrial field. The boron nitride particles may be primary particles of boron nitride that are formed into a scale shape, for example, or may be secondary particles that are aggregations of primary particles.

Examples of boron nitride that constitutes the boron nitride particles include hexagonal boron nitride (h-BN), cubic boron nitride (c-BN) and wurtzite boron nitride. From the viewpoint of a high thermal conductivity and a low thermal expansion, at least one selected from hexagonal boron nitride (h-BN) and cubic boron nitride (c-BN) is preferable, and from the viewpoint of mold processability, hexagonal boron nitride (h-BN), which is a soft boron nitride, is more preferable.

The shape of the boron nitride particles is not particularly restricted, and boron nitride particles having a scale shape, a globular shape, a rod shape, a crushed shape, a round shape or the like may be used. The boron nitride particles usually have a scale shape, and either the scale-shaped particles or aggregated particles formed by the scale-shaped particles may be used as the boron nitride particles.

The average particle size of the boron nitride particles is not particularly restricted. From the viewpoint of a high thermal conductivity and a high filling ability, the average particle size is preferably from 10 μm to 200 μm, more preferably from 20 μm to 150 μm, further preferably from 30 μm to 100 μm, and particularly preferably from 30 μm to 60 μm. When the average particle size is 10 μm or more, thermal conductivity tends to be further improved. When the average particle size is 200 μm or less, both a thermal conductivity and a high filling ability tend to be attained, and anisotropy of the particle shape can be prevented from becoming too large, whereby dispersion in thermal conductivity tends to be suppressed.

The average particle size of the boron nitride particles is measured as a volume average particle size with a laser diffraction scattering-type particle size distribution analyzer by a wet method. When a laser diffraction scattering method is used, the measurement can be performed by extracting a filler from a resin composition or a resin sheet (including cured products thereof) and carrying out the measurement of the extracted filler with a laser diffraction scattering-type particle size distribution analyzer (for example, LS230, manufactured by Beckman Coulter Inc.) Whether or not the filler is boron nitride particles can be determined by measuring an X-ray diffraction spectrum (XRD) of the filler.

The content ratio of the alumina particles and the boron nitride particles in the filler is not particularly restricted. From the viewpoint of attaining a strength and a thermal conductivity, the mass ratio of alumina particles and boron nitride particles (alumina particles:boron nitride particles) is preferably 20 mass % to 80 mass %:80 mass % to 20 mass %, wherein the total mass of alumina particles and boron nitride particles is 100 mass %. From the viewpoint of attaining a further improvement in strength, the ratio is more preferably 30 mass % to 70 mass %:70 mass % to 30 mass %. From the viewpoint of attaining both the strength and the thermal conductivity at even higher levels, the ratio is particularly preferably 40 mass % to 60 mass %:60 mass % to 40 mass %.

When the content of alumina particles in the total mass of alumina particles and boron nitride particles is 80 mass % or less, the thermal conductivity tends to become high, whereby both the thermal conductivity and the strength of a cured object tend to be attained. When the content of boron nitride particles is 80 mass % or less, the strength of a cured object tends to become high, whereby both the strength and the thermal conductivity tend to be attained.

In the present invention, the content of the whole filler in the resin composition is not particularly restricted. The content is preferably from 30 vol % to 95 vol % in the total solid volume of the resin composition, more preferably from 35 vol % to 80 vol %, still more preferably from 40 vol % to 60 vol %. When the content is 30 vol % or more, thermal conductivity of the resin composition tends to become higher. When the content is 95 vol % or less, moldability of the resin composition tends to further improve. The total solid volume of the resin composition refers to the total volume of nonvolatile components among the components that constitute the resin composition.

(Other Fillers)

The filler may include a filler other than alumina particles or boron nitride particles, as needed. Examples of the filler other than alumina particles or boron nitride particles include non-conducting fillers such as magnesium oxide, aluminum nitride, silicon nitride, silicon oxide, aluminum hydroxide and barium sulfate, and conducting fillers such as gold, silver, nickel and copper. These fillers may be used singly or in combination of two or more kinds thereof.

[Elastomer]

The resin composition includes at least one kind of elastomer having a weight-average molecular weight of from 10,000 to 100,000.

In a resin composition including boron nitride particles, a surface treatment of the boron nitride particles is generally performed in order to improve the performances thereof. In this way, for example, generation of voids in the resin composition due to boron nitride particles can be reduced. However, simply performing a surface treatment to boron nitride particles may not be enough to achieve a sufficient outcome in some cases. In this regard, the present inventors have focused on the other components that constitute the resin composition, and found that occurrence of failures due to boron nitride particles can be suppressed by improving the properties of other components without directly performing a surface treatment of boron nitride particles. More specifically, in the present invention, the viscosity of the resin composition as a whole is decreased by using an elastomer having a specified weight-average molecular weight to cover at least a part of the surface of alumina particles that exist as a filler together with boron nitride particles. In this way, an increase in viscosity caused by addition of boron nitride particles is cancelled, and the performances of the resin composition as a whole can be improved.

The elastomer is not particularly restricted as long as the weight-average molecular weight is from 10,000 to 100,000, and may be selected from those commonly used. From the viewpoint of compatibility with a curable resin, the weight-average molecular weight of the elastomer is preferably from 10,000 to 50,000. From the viewpoint of filler dispersibility, the weight-average molecular weight of the elastomer is more preferably from 10,000 to 30,000. The weight-average molecular weight of the elastomer is measured with a GPC device. More specifically, the measurement is performed with a GPC device (manufactured by GASUKURO KOGYO, LC COLOMN OVEN; HITACHI L-3300 RI Monitor; HITACHI L-6200 Intelligent Pump) using THF as a solvent. Detailed measurement conditions are as follows.

Column: three columns below

TSKgel SuperMultiporeHZ-N 21815

TSKgel SuperMultiporeHZ-M 21488

TSKgel SuperMultiporeHZ-H 21885
(the above columns are manufactured by Tosoh Corporation)

Eluent: tetrahydrofuran

Measuring temperature: 25° C.

Flow rate: 1.00 mL/min.

When the weight-average molecular weight of the elastomer is less than 10,000, dispersibility of a filler may not be sufficient and the viscosity of the resin composition may not be sufficiently reduced. When the weight-average molecular weight of the elastomer is higher than 100,000, the viscosity of the resin composition may not be sufficiently reduced.

The reason for this can be thought, for example, as follows. In a case of a low molecular weight elastomer having a low weight-average molecular weight of less than 10,000, the number of active sites (functional groups) in the molecule that can interact with a surface of a filler is limited. When the number of the active sites is small, an attractive interaction with functional groups at a surface of a filler may not be sufficient. Alternatively, even when an elastomer is attached temporarily to a surface of a filler, the attachment may not be stable due to the influence of other surrounding substances or processes, and the elastomer may be detached from the filler. As a result, an improvement in dispersibility of the filler may not be sufficient, and the viscosity of the resin composition may not be sufficiently reduced.

On the other hand, when the weight-average molecular weight of the elastomer is greater than 100,000, the molecular chain of the elastomer may become too long, and the dispersibility of the filler may decrease, whereby the viscosity of the resin composition may not be sufficiently reduced. Accordingly, in the present invention, it is important to use an elastomer having a molecular weight in an appropriate range.

The elastomer preferably has at least one kind of polarizable functional group.

The term “polarizable functional group” (hereinafter, also referred to as a “polarizable group”) refers to a functional group that includes two or more kinds of atoms having different electronegativity, and has a dipole moment. Examples of the polarizable group include a carboxy group, an ester group, a hydroxy group, a carbonyl group, an amide group and an imide group. From the viewpoint of adsorptivity to alumina particles, the polarizable group is preferably at least one selected from the group consisting of a carboxy group, an ester group and a hydroxy group.

When the elastomer has a polarizable functional group, it becomes possible for a polarizable functional group to form a hydrogen bond or electrostatically interact with an oxygen atom at the surface of a filler (preferably alumina particles). Therefore, an elastomer including a polarizable functional group can be efficiently attached to the surface of the filler, and at least a part of the surface of a filler (preferably alumina particles) can be efficiently covered with the elastomer. Further, the surface of the filler is smoothed because of an elastomer existing thereon, and the viscosity of a resin composition is decreased. Moreover, flexibility of a resin sheet formed from the resin composition is improved. In addition, it is thought that the adhesive strength between the resin sheet and a metal substrate is improved as a result of stress relaxation caused by the improvement in flexibility.

The content of the polarizable group included in the elastomer is not particularly restricted. The content of the structural unit having a polarizable group in a resin that constitutes an elastomer is preferably 30 mole % or more, more preferably 50 mole % or more.

When the content of the polarizable group is in the above range, dispersibility of the filler is further improved.

The kind of the resin that constitutes the elastomer is not particularly restricted, as long as the resin exhibits a rubber elasticity within a range of the weight-average molecular weight as mentioned above. Specific examples of the elastomer include silicone elastomer, nitrile elastomer and acrylic elastomer. From the viewpoint of attachability with respect to a surface of a filler, an acrylic elastomer is preferred.

In general, since an acrylic elastomer is mainly formed of a structural unit having a polarizable functional group such as an ester group, an acrylic elastomer tends to have an excellent attachability with respect to a surface of a filler, whereby an effect of dispersing a filler is more significant. The acrylic elastomer preferably includes, as a primary component, a structural unit represented by following Formula (1).

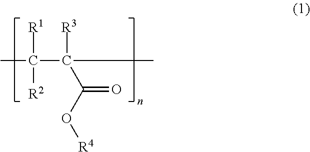

In Formula (1), each of R¹, R² and R³ independently represents a linear or branched alkyl group or a hydrogen atom. R⁴ represents a linear or branched alkyl group. n is an integer that indicates that the structural unit is a repeating unit. When the acrylic elastomer includes two or more kinds of structural units represented by Formula (1) and there are two or more kinds of R¹ to R⁴, the two or more kinds of R¹ to R⁴ may be the same or different from each other.

In Formula (1), when each of R¹, R² and R³ independently represents a linear or branched alkyl group, from the viewpoint of imparting softness, the number of carbon atoms of the alkyl group is preferably from 1 to 12, and from the viewpoint of achieving a low Tg, the number of carbon atoms of the alkyl group is more preferably from 1 to 8.

In a preferred embodiment of the invention, each of R¹ and R² is a hydrogen atom. R³ is a hydrogen atom or a methyl group, more preferably a hydrogen atom.

In Formula (1), from the viewpoint of imparting softness, the number of carbon atoms of the alkyl group represented by R⁴ is, preferably from 4 to 14. From the viewpoint of achieving a low Tg, the number of carbon atoms of the alkyl group is more preferably from 4 to 8.

By using an acrylic elastomer including, as a main component, a structural unit represented by Formula (1), it becomes possible to impart a resin composition with a soft structure (softness). For this reason, a resin sheet formed by using this resin composition may overcome a failure that occurs in a conventional resin sheet, such as a decrease in flexibility of the sheet caused by increasing the amount of a filler.

The content of the structural unit represented by Formula (1) in the acrylic elastomer is not particularly restricted. For example, from the viewpoint of the filler dispersibility, the content of the structural unit is preferably 30 mole % or higher, more preferably 50 mole % or higher.

In one embodiment of the present invention, an acrylic elastomer having at least a structural unit represented by Formula (1) in the molecule preferably further includes a structural unit having a carboxy group or a hydroxy group in the molecule, more preferably further includes a structural unit having a carboxy group in the molecule.

When an acrylic elastomer includes a structural unit having a carboxy group, for example, a carboxy group interacts with a hydroxy group at a surface of a filler, thereby further improving an effect of performing a surface treatment to the filler. By an effect of a surface treatment, wettability between the filler and the elastomer is more improved and the viscosity of a resin composition is more decreased, whereby application of the resin composition tends to become easier. Further, the filler is highly dispersed as a result of improving in wettability, which also contributes to an improvement in thermal conductivity. Moreover, a carboxy group is capable of causing crosslinking reaction with a curable resin such as an epoxy resin during curing reaction. As a result, a cross-linking density is increased, thereby further improving thermal conductivity. In addition, since a carboxy group is capable of releasing a hydrogen ion, it is possible to cause ring opening of an epoxy group during the curing reaction and bring about an effect as a catalyst.

In a case in which the acrylic elastomer has a carboxy group, the content of the carboxy group in the acrylic elastomer is not particularly restricted. From the viewpoint of filler dispersibility, the content of the structural unit having a carboxy group in a resin that constitutes the acrylic elastomer is preferably from 10 mole % to 50 mole %, more preferably from 20 mole % to 50 mole %.

In an embodiment of the invention, an acrylic elastomer having at least a structural unit represented by Formula (1) in the molecule preferably further includes a structural unit having an amino group in the molecule. From the viewpoint of preventing moisture absorption, the structural unit having an amino group is preferably a structural unit including a secondary amine structure or a tertiary amine structure. From the viewpoint of improvement in thermal conductivity, a structural unit including an N-methyl piperidino group is particularly preferable. When an acrylic elastomer has a structural unit including an N-methyl piperidino group, compatibility is remarkably improved due to an interaction with a phenolic curing agent as described below. When a resin composition includes an acrylic elastomer having an excellent compatibility, a loss in thermal conductivity tends to become smaller. The interaction between the N-methyl piperidino group and the phenolic curing agent exhibits a stress relaxation effect due to sliding between different kinds of molecules, thereby contributing to an improvement in adhesion.

When the acrylic elastomer has a structural unit including an amino group, the content of the amino group in the acrylic elastomer is not particularly restricted. From the viewpoint of compatibility, the content of the amino group in the acrylic elastomer is preferably from 0.5 mole % to 3.5 mole %, more preferably from 0.5 mole % to 2.0 mole %.

In one embodiment of the present invention, a copolymer having a structure represented by following Formula (2) is preferably used as an acrylic elastomer.

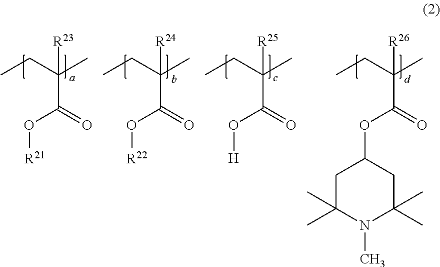

In Formula (2), a, b, c and d at each of the structural units that constitute a polymer indicate the contents (mole %) of the structural units in the total structural units, and the total of a, b, c and d is 90 mole % or higher. Each of R²¹ and R²² independently represents a linear or branched alkyl group, and the alkyl groups represented R²¹ and R²² are different in carbon number. Each of R²³ to R²⁶ independently represents a hydrogen atom or a methyl group.

The total of a, b, c and d is 90 mole % or higher, preferably 95 mole % or higher, more preferably 99 mole % or higher.

In the acrylic elastomer represented by Formula (2), a structural unit that is present at a ratio of “a” (hereinafter, also referred to as “structural unit a”) can impart a sheet with flexibility, and enables achievement of both thermal conductivity and flexibility. A structural unit that is present at a ratio of “b” (hereinafter, also referred to as “structural unit b”) further improves the flexibility of a resin sheet in combination with structural unit a. The chain lengths of the alkyl groups represented by R²¹ and R²² in structural units a and b, which provide a soft structure (softness), are not particularly limited. By appropriately selecting the upper limit for the chain length of alkyl groups represented by R²¹ and R²², the Tg of the acrylic elastomer can be prevented from becoming too high, thereby obtaining a more excellent effect of improving flexibility. On the other hand, by appropriately selecting the lower limit of the chain length of the alkyl groups represented by R²¹ and R²², the acrylic elastomer's own softness is improved and an effect of including the acrylic elastomer can be sufficiently achieved. From this point of view, the carbon numbers of the alkyl groups represented by R²¹ and R²² are preferably in a range of from 2 to 16, preferably in a range of from 4 to 12.

The alkyl groups represented by R²¹ and R²² have different carbon numbers. The difference between the carbon numbers of R²¹ and R²² is not particularly restricted. From the viewpoint of a balance between flexibility and softness, the difference between the carbon numbers is preferably from 4 to 10, more preferably from 6 to 8.

From the viewpoint of a balance between flexibility and softness, a combination in which the number of carbon atoms of R²¹ is from 2 to 6 and the number of carbon atoms of R²² is from 8 to 16 is preferred, and a combination in which the number of carbon atoms of R²¹ is from 3 to 5 and the number of carbon atoms of R²² is from 10 to 14 is more preferred.

In Formula (2), the contents (mole %) of structural units a and b are not particularly limited, and the content ratio between structural units a and b is also not particularly restricted. From the viewpoint of flexibility of a resin sheet and filler dispersibility, the content of structural unit a is preferably from 50 mole % to 85 mole %, more preferably from 60 mole % to 80 mole %. The content of structural unit b is preferably from 2 mole % to 20 mole %, more preferably from 5 mole % to 15 mole %. The content ratio of structural unit a with respect to structural unit b (structural unit a/structural unit b) is preferably from 4 to 10, more preferably from 6 to 8.

In Formula (2), since there is a carboxy group in an acrylic elastomer, which is derived from a structural unit that is present at a ratio of “c” (hereinafter, also referred to as “structural unit c”), effects such as an improvement in thermal conductivity and an improvement in wettability between a filler and a resin can be obtained. Further, since there is an N-methyl piperidino group in an acrylic elastomer, which is derived from a structural unit that is present at a ratio of “d” (hereinafter, also referred to as “structural unit d”), effects such as an improvement in compatibility and an improvement in adhesion can be obtained. These effects are more significant when both a carboxy group and an N-methyl piperidino group exist in the acrylic elastomer. More specifically, an N-methyl piperidino group is capable of accepting a hydrogen ion from a carboxy group, and then interacting with, for example, a phenolic hydroxy group included in a curing agent. This interaction with a phenolic hydroxy group improves the compatibility between the acrylic elastomer and a curable composition system. In addition, when there is an interaction between a carboxy group and an N-methyl piperidino group, the whole molecule of the acrylic elastomer has a curbed structure, rather than a straight structure, which enhances the contribution to stress relaxation of a decrease in elasticity.

In view of the above, in an embodiment of the acrylic elastomer represented by Formula (2), the content of structural unit c is in a range of from 10 mole % to 30 mole %, more preferably in a range of from 14 mole % to 28 mole %, and the content of structural unit d is in a range of from 0.5 mole % to 5 mole %, more preferably in a range of from 0.7 mole % to 3.5 mole %.

From the viewpoint of thermal conductivity, insulation, adhesion and sheet flexibility, in a preferred embodiment of the acrylic elastomer represented by Formula (2), R²¹ and R²² are an alkyl group having 2 to 16 carbon atoms, the difference in the number of carbon atoms of R²¹ and R²² is 4 to 10, a is from 50 mole % to 85 mole %, b is from 2 mole % to 20 mole %, c is from 10 mole % to 30 mole %, d is from 0.5 mole % to 5 mole %, and the total of a, b, c and d is from 90 mole % to 100 mole %. More preferably, R²¹ and R²² are an alkyl group having 4 to 12 carbon atoms, the difference in the carbon number of R²¹ and R²² is from 6 to 8, a is from 60 mole % to 80 mole %, b is from 5 mole % to 15 mole %, c is from 14 mole % to 28 mole %, d is from 0.7 mole % to 3.5 mole %, the total of a, b, c and d is from 95 mole % to 100 mole %, and a/b is from 4 to 10.

In an embodiment of the invention, a copolymer having a structure represented by following Formula (3) is also preferably used as an acrylic elastomer.

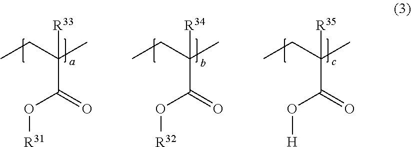

In formula (3), a, b and c at each of the structural units indicate the contents (mole %) of the structural units in the total structural units that constitute a copolymer, wherein the total of a, b and c is 90 mole % or higher. Each of R³¹ and R³² independently represents a linear or branched alkyl group and the alkyl groups represented by R³¹ and R³² have different carbon numbers. Each of R³³ to R³⁵ independently represents a hydrogen atom or a methyl group.

The total of a, b and c is 90 mole % or higher, preferably 95 mole % or higher, more preferably 99 mole % or higher.

In the acrylic elastomer represented by Formula (3), the structural unit that is present at a ratio of “a” (hereinafter, also referred to as “structural unit a”) can impart a sheet with flexibility, and makes it possible to attain both thermal conductivity and flexibility. A structural unit that is present at a ratio of “b” (hereinafter, also referred to as “structural unit b”) further improves the flexibility of a resin sheet in combination with structural unit a. The chain lengths of the alkyl groups represented by R³¹ and R³² that impart a soft structure (softness) are not particularly limited. By appropriately selecting the upper limit of the chain length of the alkyl groups represented by R³¹ and R³², the Tg of the acrylic elastomer can be prevented from becoming too high, and a more excellent effect of improving flexibility can be obtained. On the other hand, by appropriately selecting the lower limit of the chain length of the alkyl groups represented by R³¹ and R³², the acrylic elastomer's own softness is further improved and an effect achieved by including an acrylic elastomer can be sufficiently obtained. From this point of view, the carbon number of the alkyl groups represented by R³¹ and R³² are preferably in a range of from 2 to 16, preferably in a range of from 4 to 12.

The alkyl groups represented by R³¹ and R³² have different carbon numbers. The difference in the carbon number in R³¹ and R³² is not particularly restricted. From the viewpoint of a balance between flexibility and softness, the difference in the carbon number is preferably from 4 to 10, more preferably from 6 to 8.

Further from the viewpoint of a balance between flexibility and softness, preferably, the carbon number of the alkyl group represented by R³¹ is from 2 to 6 and the carbon number of the alkyl group represented by R³² is from 8 to 16. More preferably, the carbon number of the alkyl group represented by R³¹ is from 3 to 5 and the carbon number of the alkyl group represented by R³² is from 10 to 14.

In Formula (3), the contents (mole %) of structural unit a and structural unit b are not particularly limited, and the content ratio between structural unit a and structural unit b is also not particularly restricted. From the viewpoint of flexibility of a resin sheet and filler dispersibility, the content of structural unit a is preferably from 50 mole % to 85 mole %, more preferably from 60 mole % to 80 mole %. The content of structural unit b is preferably from 2 mole % to 20 mole %, more preferably from 5 mole % to 15 mole %. Further, the content ratio of structural unit a with respect to structural unit b (structural unit a/structural unit b) is preferably from 4 to 10, more preferably from 6 to 8.

In Formula (3), since there is a carboxy group derived from a structural unit that is present at a ratio of “c” (hereinafter, also referred to as “structural unit c”), effects such as an improvement in thermal conductivity and an improvement in wettability between a filler and a resin are obtained.

From this point of view, in an embodiment of the acrylic elastomer represented by Formula (3), the content of structural unit c is in a range of from 10 mole % to 30 mole %, more preferably in a range of from 14 mole % to 28 mole %.

In the acrylic elastomer represented by Formula (3), from the viewpoint of thermal conductivity, insulation, adhesion and sheet flexibility, preferably, R³¹ and R³² are an alkyl group having 2 to 16 carbon atoms, the difference in the carbon number of the alkyl groups represented by R³¹ and R³² is 4 to 10, a is from 50 mole % to 85 mole %, b is from 2 mole % to 20 mole %, c is from 10 mole % to 30 mole %, and the total of a, b and c is from 90 mole % to 100 mole %. More preferably, R³¹ and R³² are an alkyl group having 4 to 12 carbon atoms, the difference in the carbon number of the alkyl groups represented by R³¹ and R³² is from 6 to 8, a is from 60 mole % to 80 mole %, b is from 5 mole % to 15 mole %, c is from 14 mole % to 28 mole %, the total of a, b and c is from 95 mole % to 100 mole %, and a/b is from 4 to 10.

The content of the elastomer in the resin composition may be in a range of from 0.1 parts by mass to 99 parts by mass, where the total mass of the curable resin mentioned below is 100 parts by mass. From the viewpoint of filler dispersibility, the content of the elastomer in the resin composition is preferably in a range of from 1 part by mass to 20 parts by mass. From the viewpoint of a high thermal conductivity, the content of the elastomer in the resin composition is further preferably in a range of from 1 part by mass to 10 parts by mass, particularly preferably in a range of from 3 parts by mass to 10 parts by mass.

From the viewpoint of filler dispersibility, the content of the elastomer in the resin composition is preferably in a range of from 0.1 parts by mass to 10 parts by mass, more preferably in a range of from 0.5 parts by mass to 5 parts by mass, further preferably in a range of from 1 part by mass to 4 parts by mass, where the total mass of the alumina particles is 100 parts by mass.

When the content of the elastomer is in the range as described above, the viscosity of the resin composition can be lowered without inhibiting the thermal conductivity of a curable resin, and effects such as disappearance of voids and an improvement in wettability can be achieved. Further, the surface of the alumina particles can be sufficiently covered, thereby sufficiently achieving an effect of dispersing the alumina particles. In addition, a decrease in thermal conductivity of the resin composition as a whole tends to be suppressed. Accordingly, by adjusting the content of the elastomer to be in the range as described above, it becomes easy to achieve a favorable balance among a variety of properties.

[Curable Resin]

The curable resin is not particularly limited as long as it can be cured by heat or light. Specific examples of the curable resin include an epoxy resin, a phenol resin, a polyimide resin and a polyurethane resin. From the viewpoint of excellent adhesion, at least one selected from an epoxy resin and a polyurethane resin is preferable. From the viewpoint of adhesion and electric insulation, an epoxy resin is more preferable.

Examples of the epoxy resin include a bisphenol F epoxy resin, a bisphenol S epoxy resin, a phenol novolac epoxy resin, a cresol novolac epoxy resin, a naphthalene epoxy resin and an alicyclic epoxy resin. From the viewpoint of a high thermal conductivity, an epoxy resin having a mesogene group such as a biphenyl group, which has a structure that is prone to self-arrangement, in the molecule is preferably used. An epoxy resin having a mesogene group in the molecule is disclosed, for example, in JP-A No. 2005-206814. Examples of the epoxy resin having a mesogene group in the molecule include 1-{(3-methyl-4-oxiranylmethoxy)phenyl}-4-(4-oxiranylmethoxyphenyl)-1-cyclohexene, 1-{(3-methyl-4-oxiranylmethoxy)phenyl}-4-(4-oxiranylmethoxyphenyl)benzene, and 1,4-bis{4-(oxiranylmethoxy)phenyl}cyclohexane. From the viewpoint of a low melting temperature, 1-{(3-methyl-4-oxiranylmethoxy)phenyl}-4-(4-oxiranylmethoxyphenyl)-1-cyclohexene is preferred. By using such a specified epoxy resin, it becomes possible to perform melt mixing with a curing agent at a curing temperature (preferably 120° C.) or lower. Therefore, it becomes possible to meet the requirements for low-temperature curing from the processing viewpoint.

The content of the curable resin in the resin composition is not particularly restricted. For example, the content is preferably from 5 mass % to 30 mass %, more preferably from 7 mass % to 20 mass %, further preferably from 7 mass % to 15 mass %, in the total solid mass of the resin composition. When the content of the curable resin is in the above-mentioned range, adhesion and thermal conductivity can be further improved. The total solid content of the resin composition refers to the total mass of nonvolatile components in the components that constitute the resin composition.

(Curing Agent)

The resin composition preferably includes at least one kind of curing agent. The curing agent is not particularly restricted, and may be selected depending on the curable resin. When the curable resin is an epoxy resin, the curing agent may be selected from commonly used curing agents for an epoxy resin. Specific examples of the curing agent include amine-based curing agents such as dicyandiamide and aromatic diamine; phenolic curing agents such as a phenol novolac resin, a cresol novolac resin and a catechol resorcinol novolac resin. From the viewpoint of improvement in thermal conductivity, the curing agent is preferably a phenolic curing agent, more preferably a phenolic curing agent including a substructure derived from a bifunctional phenolic compound such as catechol, resorcinol or p-hydroquinone.

When the resin composition includes a curing agent, the content of the curing agent in the resin composition is not particularly restricted. For example, the content of the curing agent may be from 0.1 to 2, preferably from 0.5 to 1.5, based on the equivalence with respect to the curable resin. When the content of the curing agent is in the above-mentioned range, adhesion and thermal conductivity can be further improved.

(Curing Catalyst)

The resin composition preferably includes at least one curing catalyst. The curing catalyst is not particularly restricted, and may be selected from the commonly used curing catalysts depending on the kind of the curable resin. When the curable resin is an epoxy resin, specific examples of the curing catalyst include triphenylphosphine, 2-ethyl-4-methylimidazole, boron trifluoride-amine complexes and 1-benzyl-2-methylimidazole. From the viewpoint of a high thermal conductivity, triphenylphosphine is preferred.

When the resin composition includes a curing catalyst, the content of the curing catalyst in the resin composition is not particularly restricted. For example, the content of the curing catalyst may be from 0.1 mass % to 2.0 mass %, preferably from 0.5 mass % to 1.5 mass %, with respect to the curable resin. When the content of the curing catalyst is in the above-mentioned range, adhesion and thermal conductivity can be further improved.

(Coupling Agent)

The resin composition preferably includes at least one kind of silane coupling agent in addition to a curable resin, an elastomer and a filler containing alumina particles and boron nitride particles which are essential components. A silane coupling agent may be included for the purpose of, for example, performing a surface treatment of the filler.

The silane coupling agent is not particularly restricted, and may be selected from commonly used silane coupling agents. Specific examples of the silane coupling agent include methyl trimethoxysilane (manufactured by Shin-Etsu Chemical Co., Ltd., available as KBM-13), 3-mercaptopropyl trimethoxysilane (manufactured by Shin-Etsu Chemical Co., Ltd., available as KBM-803), 3-triethoxysiyl-N-(1,3-dimethyl-butylidene)propylamine (manufactured by Shin-Etsu Chemical Co., Ltd., available as KBE-9103), N-phenyl-3-aminopropyl trimethoxy silane (manufactured by Shin-Etsu Chemical Co., Ltd., available as KBM-573), 3-aminopropyl trimethoxy silane (manufactured by Shin-Etsu Chemical Co., Ltd., available as KBM-903) and 3-glycidyloxypropyl trimethoxysilane (manufactured by Shin-Etsu Chemical Co., Ltd., available as KBM-403). From the viewpoint of a high thermal conductivity, N-phenyl-3-aminopropyl trimethoxy silane is preferred.

When the resin composition includes a silane coupling agent, the content of the silane coupling agent in the resin composition is not particularly restricted. For example, the content of the silane coupling agent in a filler may be from 0.1 mass % to 1.0 mass %, preferably from 0.1 mass % to 0.5 mass %. When the content of the silane coupling agent is in the above-mentioned range, thermal conductivity can be further improved.

(Solvent)

The resin composition may include at least one kind of solvent. The solvent is not particularly restricted as long as it does not inhibit a curing reaction of the resin composition, and may be appropriately selected from commonly used organic solvents. Specific examples of the solvent include a ketone solvent such as methyl ethyl ketone and cyclohexanone.

The content of the solvent in the resin composition is not particularly restricted, and may be selected depending on the application properties or the like of the resin composition.

<Resin Sheet>

The resin sheet of the present invention is a product formed by molding the resin composition in a sheet shape. The resin sheet can be manufactured, for example, by applying the resin composition onto a mold release film, and removing a solvent included in the resin composition as needed.

Since the resin sheet is formed from the resin composition, it has an excellent thermal conductivity and an excellent flexibility.

The resin sheet is formed by molding the resin composition in a sheet shape, and is preferably a B-stage sheet that is obtained by further performing a heat treatment until the resin sheet is in a semi-cured state (B-stage state). The B-stage sheet has a viscosity of from 10⁴ Pa·s to 10⁵ Pa·s at normal temperature (25° C.), but it decreases to from 10² Pa·s to 10³ Pa·s at 100° C. On the other hand, a cured resin sheet after curing, which is described below, does not melt even by heating. The above-mentioned viscosity is measured by a dynamic viscoelasticity measurement (frequency: 1 Hz, load: 40 g, rate of temperature increase: 3° C./min.)

A B-stage sheet can be manufactured in the following manner, for example.

A resin composition layer can be obtained by applying a varnish of the resin composition to which a solvent such as methyl ethyl ketone or cyclohexanone is added onto a mold release film such as a PET film, and then removing at least a part of the solvent. Application can be carried out by a known method. Examples of the application method include comma coating, die coating, lip coating and gravure coating. As an application method for forming a resin composition layer in a predetermined thickness, a comma coating method in which a material to be coated is passed through a gap, a die coating method in which the flow rate of the resin varnish from a nozzle is adjusted, or the like may be applied. For example, when the thickness of a resin composition layer before drying is from 50 μm to 500 μm, a comma coating method is preferably used.

The resin composition layer formed by the application process has flexibility because of little advancement in curing reaction. However, the resin composition layer lacks softness as a sheet and self-supporting properties upon removal of a PET film as a support, and it is difficult to handle. Therefore, the resin composition layer is preferably made into a B-stage sheet by performing a heat treatment as described below.

The conditions for the heat treatment for the resin composition layer are not particularly restricted as long as the resin composition is semi-cured to become a B-stage state, and may be selected depending on the constitution of a resin composition that forms the resin composition layer. The heat treatment is preferably performed by a heat treatment method selected from the group consisting of vacuum hot pressing, hot roll lamination, and the like. By selecting these methods, the voids formed in the resin composition layer during the application process can be reduced, and a flat B-stage sheet can be efficiently manufactured.

Specifically, the resin composition layer formed from a resin composition can be semi-cured to become a B-stage state by, for example, performing a heat press treatment at a heating temperature of from 80° C. to 130° C., for from 1 second to 30 seconds, under a reduced pressure (for example, 1 MPa).

The thickness of the B-stage sheet may be selected depending on the purposes. For example, the thickness of the B-stage sheet may be from 50 μm to 500 μm. From the viewpoint of thermal conductivity and sheet flexibility, the thickness of the B-stage sheet is preferably from 100 μm to 300 μm. The B-stage sheet may be produced by layering two or more resin composition layers and subjecting the same to a heat press treatment.

<Cured Resin Sheet>

The cured resin sheet of the present invention is a cured object of the resin sheet. The method of curing a resin sheet may be selected depending on the constitution of a resin composition or the purpose of the cured resin sheet, and a heat press treatment is preferred. The conditions for the heat press treatment is preferably, for example, a heating temperature of from 80° C. to 250° C. and a pressure of from 0.5 MPa to 8.0 MPa, more preferably a heating temperature of from 130° C. to 230° C. and a pressure of from 1.5 MPa to 5.0 MPa.

The treatment time for the heat press treatment may be selected depending on the heating temperature or the like. For example, the treatment time may be from 30 minutes to 2 hours, preferably from 1 hour to 2 hours.

The heat press treatment may be performed once, or may be performed twice or more by changing the heating temperature or the like.

<Heat Dissipation Device>

The heat dissipation device of the present invention at least includes a metal work and the resin sheet or the cured resin sheet that is disposed on the metal work so as to contact the metal work.

The term “metal work” herein refers to a molded article that is made of a metal material that can function as a heat dissipation device, and includes a substrate, a fin and the like. In one embodiment of the invention, the metal work is preferably a substrate formed of a metal such as Al (aluminum) or Cu (copper).

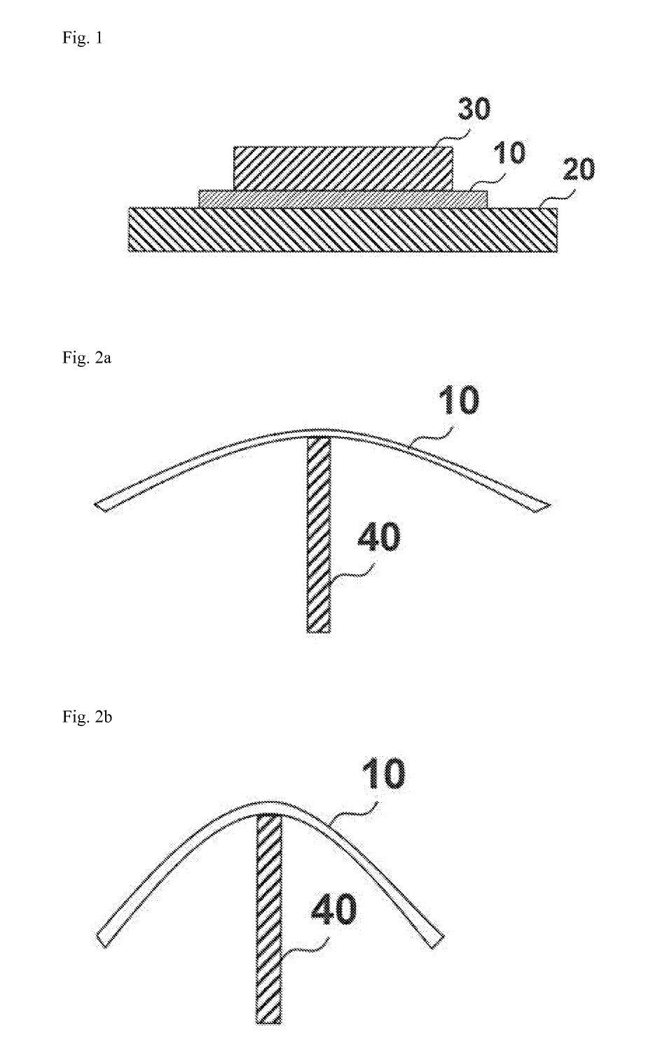

As one embodiment of a heat dissipation device of the invention, a heat dissipation device using a resin sheet obtained by molding the resin composition in a sheet shape is illustrated in FIG. 1.

In FIG. 1, the resin sheet 10 is positioned between a first metal work 20 composed of, for example, Al (aluminium) and a second metal work 30 composed of, for example, Cu (copper). One surface of the resin sheet is attached to the surface of the metal work 20 and the other surface of the resin sheet is attached to the surface of the metal work 30. The resin sheet 10 has an excellent flexibility, and at the same time, can attain an excellent adhesion with respect to the contact surfaces of the first and second metal works 20 and 30.

From the viewpoint of adhesion, in general, the resin sheet used for the attachment to a metal work desirably has a shear strength of 5 MPa or higher. As shown in the Examples below, a resin sheet that satisfies the above-mentioned shear strength can be provided by the invention. Since a resin sheet 10 has an excellent thermal conductivity, for example, it is possible to efficiently conduct heat generated at the second metal work 30 composed of Cu to the first metal work 20 composed of Al via the resin sheet 10, and release the heat outside.

<Resin-Adhered Metal Foil>

The resin-adhered metal foil of the present invention includes a metal foil and a resin composition layer, which is a coating of the resin composition, disposed on the metal foil. Since the metal foil has a resin composition layer derived from the resin composition, the foil has an excellent thermal conductivity, an excellent electric insulation and an excellent flexibility.

The resin composition layer may be a coating film of the resin composition. Preferably, the resin composition layer is a semi-cured resin layer obtained by performing a heat treatment such that the resin composition becomes in a B-stage state.

The metal foil is not particularly restricted and may be a gold foil, a copper foil, an aluminum foil or the like. A copper foil is generally used.

The thickness of the metal foil is not particularly restricted. For example, the thickness may be from 1 μm to 110 μm. In particular, by using a metal foil having a thickness of 35 μm or less, flexibility is further improved.

The metal foil may be a combined foil having a three-layer structure or a two-layer structure. The metal foil having a three-layer structure may include an intermediate layer formed of nickel, nickel-phosphorus, nickel-tin alloy, nickel-iron alloy, lead, lead-tin alloy or the like, which is disposed between a copper layer having a thickness of from 0.5 μm to 15 μm and a copper layer having a thickness of from 10 μm to 300 μm. The metal foil having a two-layer structure may be formed of an aluminum foil and a copper foil.

The resin-adhered metal foil may be manufactured by forming a resin composition layer by applying the resin composition including a solvent (hereinafter, also referred to as a “resin varnish”) on the metal foil and drying. The method of forming a resin composition layer is as described above.

The conditions for manufacturing a resin-adhered metal foil are not particularly restricted. Preferably, 80 mass % or more of a solvent used in the resin varnish has been vaporized from the resin composition layer after drying. The drying temperature may be, for example, about 80° C. to 180° C. The drying time may be determined in view of the time for gelling of the resin varnish, and not particularly restricted. The amount of application of the resin varnish is preferably determined such that the thickness of the resin composition layer after drying is from 50 μm to 200 μm, more preferably from 60 μm to 150 μm.

The resin composition layer after drying is preferably in a B-stage state by performing a heat treatment. The conditions for the heat treatment of the resin composition layer are the same as the conditions for the heat press treatment to the B-stage sheet.

### EXAMPLES

The present invention will be described more specifically by the Examples. However, the present invention is not limited to the Examples.

(Synthesis of Catechol Resorcinol Novolac (CRN) Resin)

In a 3 L-separable flask provided with a stirrer, a cooler and a thermometer, 594 g of resorcinol, 66 g of catechol, 316.2 g of 37 mass % formalin, 15 g of oxalic acid and 100 g of water were placed and the temperature was elevated to 100° C. by heating in an oil bath. At this refluxing temperature, the reaction was allowed to continue for four hours. Then, the temperature in the flask was elevated to 170° C. while distilling off water, and the reaction was allowed to continue for eight hours while maintaining the temperature at 170° C.

Thereafter, condensation was performed for 20 minutes under a reduced pressure for removing water or the like from the system, and a catechol resorcinol novolac (CRN) resin was taken out. The number average molecular weight of the obtained catechol resorcinol novolac (CRN) resin was 530, and the weight-average molecular weight was 930. The hydroxyl equivalent of the catechol resorcinol novolac (CRN) resin was 65. The catechol resorcinol novolac (CRN) resin obtained by the above-mentioned synthesis was used in the Examples below.

(Synthesis of Elastomer)

The elastomer used in the Examples was synthesized in accordance with a synthesis method disclosed in JP-A No. 2010-106220. Specifically, a desired elastomer was obtained by using an appropriate solvent according to the constitution of elastomer, mixing monomer components with a polymerization initiator and the like such that a desired ratio is obtained, and copolymerizing the same by stirring and heating.

### Example 1

(1) Production of Elastomer-Containing Thermally Conductive B-Stage Sheet

In a 250-ml polyethylene bottle, 0.090 parts by mass of N-phenyl-3-aminopropyl trimethoxy silane (manufactured by Shin-Etsu Chemical Co., Ltd., trade name: KBM573), 0.5767 parts by mass of acrylic elastomer REB100-1 having the structural formula below (a synthetic product, weight-average molecular weight: 11,000) and 5.166 parts by mass of cyclohexanone solution of catechol resorcinol novolac (CRN) resin (solid content: 50 mass %) were added in this order.

In the structural formula below, the numerical values at the structural units indicates the content ratio of the structural unit by mole %.

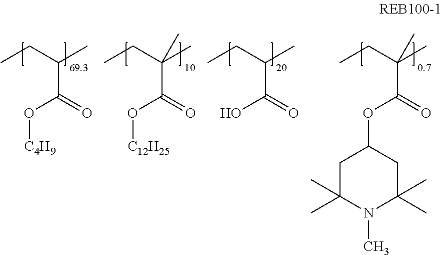

Next, after adding 150.00 parts by mass of alumina balls (size: 3 mm) to the polyethylene bottle, 21.64 parts by mass of aluminium oxide having a volume average particle size of 3 μm (manufactured by Sumitomo Chemical Company, Limited, alumina particles, AA-3) (content in the whole aluminium oxide: 70.6 vol %) and 9.02 parts by mass of aluminium oxide having a volume average particle size of 0.4 μm (manufactured by Sumitomo Chemical Company, Limited, alumina particles, AA-04) (content in the whole aluminium oxide: 29.4 vol %) were added. Further, 52.81 parts by mass of cyclohexanone was added and mixed with a big rotor. After confirming that the mixture was uniform, 8.374 parts by mass of 1-{(3-methyl-4-oxiranylmethoxy)phenyl}-4-(4-oxiranylmethoxyphenyl)-1-cyclohexene (epoxy resin), which was synthesized from 1-(3-methyl-4-hydroxyphenyl)-4-(4-hydroxyphenyl)-1-cyclohexene and epichlorohydrin by an ordinary method, and 0.093 parts by mass of triphenylphosphine (manufactured by Wako Pure Chemical Industries, Ltd.) were added and the mixture was further mixed. Then, a ball mill crushing treatment was performed for 40 hours to 60 hours. Thereafter, 32.89 parts by mass of boron nitride particles (volume average particle size: 40 μm, manufactured by MIZUSHIMA FERROALLOY CO., LTD., trade name: HP-40MF100, alumina particles:boron nitride particles=48 mass %:52 mass %) were added. A resin sheet coating liquid (resin composition) was thus obtained.

The content of the filler in the total solid of the resin composition was 44.2 vol %.

The resin sheet coating liquid was applied onto a mold release surface of a polyethylene terephthalate film (75E-0010CTR-4, manufactured by FUJIMORI KOGYO CO., LTD., hereinafter, also simply referred to as a PET film) such that the thickness was about 400 μm, and left to stand in an ordinary state for 10 minutes. Thereafter, the film was dried in a box-type oven for 10 minutes, and a resin composition layer was formed on the PET film. A PET film having a resin composition layer was placed on another PET film having a resin composition layer such that the resin composition layers were in contact with each other, and a planarization treatment was performed by heat pressing (top heating plate: 150° C., bottom heating plate: 150° C., pressure: 15 MPa, treatment time: 4 minutes). An elastomer-containing thermally conductive B-stage sheet having a thickness of 250 μm (acrylic resin (REB100-1)-containing thermally conductive B-stage sheet) was thus obtained.

The flexibility of the obtained resin sheet was evaluated by a method as described below, and the result was favorable.

(2) Production of Cured Object of Elastomer-Containing Thermally Conductive B-Stage Sheet

The PET films were peeled off from both sides of the elastomer-containing thermally conductive B-stage sheet obtained in the above-mentioned method, and the sheet was sandwiched by copper foils each having a thickness of 105 μm (GTS foil, manufactured by Furukawa Electric Co., Ltd.) and subjected to a vacuum heat pressing (top heating plate: 170° C., bottom heating plate: 170° C., degree of vacuum ≦1 kPa, pressure: 10 MPa, treatment time: 7 minutes). Then, the sheet was placed in a box-type oven and cured by performing step curing at 160° C. for 30 minutes and at 190° C. for 2 hours. From the obtained cured object sandwiched by copper foils, only copper was removed by etching with a sodium persulfate solution, and a cured object of the elastomer-containing thermally conductive B-stage sheet was obtained as a cured resin sheet.

The thermal conductivity of the obtained cured resin sheet was measured by a xenon flash method as described below, and the result was 10.8 W/mK.

(3) Attachment of Elastomer-Containing Thermally Conductive B-Stage Sheet to Metal Work

The PET films were peeled off from the elastomer-containing thermally conductive B-stage sheet that was obtained in the above method. The sheet was sandwiched by a copper plate and an aluminum plate, and subjected to a vacuum heat pressing (hot plate temperature: 140° C., degree of vacuum ≦1 kPa, pressure: 0.2 MPa, treatment time: 10 minutes). Then, the sheet was placed in a box-type oven and cured by performing step curing at 140° C. for 2 hours, at 165° C. for 2 hours, and at 190° C. for 2 hours. A heat dissipation device was thus obtained.

The shear adhesive strength at 175° C. of the heat dissipation device, attached with the REB100-1-containing thermally conductive B-stage sheet, was measured by a method as described below, and the result was 5.3 MPa.

The insulation was measured by a BDV method as described below, and the result was 3.5 kV/100 μm.

(4) Evaluation

(Resin Composition Viscosity)

The viscosity of the resin composition was measured with an E-type viscometer at a temperature of 25° C. and a rotation speed of 5.0 RPM, and the result was evaluated in accordance with the following evaluation criteria.

—Evaluation Criteria—

A: The viscosity was less than 10 Pa·s.

B: The viscosity was from 10 Pa·s to less than 100 Pa·s.

C: The viscosity was 100 Pa·s or higher.

(Flexibility)

The flexibility was judged by mainly touching a B-stage sheet before curing with a finger. The Criteria for judgment are as follows.

—Criteria for Judgment—

A: The sheet was favorable in handling, and regarded as not causing a problem during molding.

B: Although the sheet was somewhat fragile, it has practically no problem.

C: The sheet was hard and fragile, and regarded as requiring a careful handling during molding.

FIG. 2a and FIG. 2b are schematic cross sections each illustrating a state of the resin sheet during the judgment of the flexibility of the resin sheet. In the figures, reference number 10 indicates the resin sheet, and reference number 40 indicates a support. The support 40 was positioned at approximately the center of the resin sheet 10 cut into a strip shape. From the shape of the resin sheet 10 being supported by the support 40, flexibility of the resin sheet was judged. FIG. 2a shows a state of a resin sheet having poor flexibility as a result of not adding an elastomer, as represented by Comparative Example 1. FIG. 2b shows a state in which flexibility of the sheet was improved as a result of adding an elastomer having a specified molecular weight, as seen in Examples 1 to 7.

(Measurement Method of Thermal Conductivity)

The thermal diffusivity of a cured resin sheet was measured with a Xe flash method thermal diffusivity measuring device (NANOFLASH LFA447, manufactured by NETZSCH). The thermal conductivity (W/mK) was calculated by multiplying the value of the obtained thermal diffusivity by the specific heat (Cp: J/g·K) and the density (d: g/cm³). All of the measurements were conducted at 25±1° C.

The specific heat was measured by a DSC method with Pyris 1 DSC (manufactured by Perkin Elmer Japan Co., Ltd.) The density was measured by an Archimedes' principle with an electronic densimeter (SD-200L, manufactured by Alfa Mirage Co., Ltd.)

(Measurement Method of Adhesive Strength)

The shear adhesive strength of the cured resin sheet was measured by separating the copper plate and the aluminum plate from the heat dissipation device obtained above with a TENSILON Universal Tensile Testing Machine (RTC-1350A, manufactured by ORIENTEC Co., LTD.) at a test speed of 1 mm/minute and at a temperature of 175° C.

(Insulation Property)

The insulation property of the heat dissipation device obtained above was measured with a dielectric breakdown tester (YST-243-100RHO, manufactured by Yamayo Measuring Tools Co., Ltd.) by holding the heat dissipation device with cylindrical electrodes having a diameter of 25 mm at a voltage elevation rate of 500 V/s, an alternating current of 50 Hz and a cut-off current of 10 mA, at room temperature in an atmosphere.

### Example 2

An acrylic resin (REB122-4)-containing thermally conductive B-stage sheet was produced as a resin sheet in a similar manner to Example 1, except that an acrylic elastomer REB122-4 (synthetic product, weight-average molecular weight: 24,000) having the following structural formula was used in place of REB100-1.

The flexibility of the obtained resin sheet was favorable.

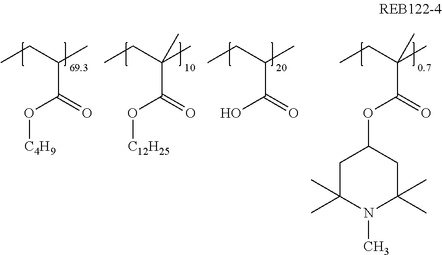

Next, a cured resin sheet was produced from the acrylic resin (REB 122-4)-containing thermally conductive B-stage sheet in a similar manner to Example 1. The thermal conductivity of the obtained cured resin sheet was measured in a similar manner to Example 1 by a xenon flash method. The thermal conductivity was 10.9 W/mK.

Further, a heat dissipation device attached with the acrylic resin (REB122-4)-containing thermally conductive B-stage sheet was produced in a similar manner to Example 1.

The shear adhesive strength at 175° C. of the obtained heat dissipation device was measured in a similar manner to Example 1, and the result was 5.4 MPa.

The insulation was measured by a BDV method in a similar manner to Example 1, and the result was 3.9 kV/100 μm.

### Example 3

An acrylic resin (REB146-1)-containing thermally conductive B-stage sheet was produced as a resin sheet in a similar manner to Example 1, except that an acrylic elastomer REB146-1 (synthetic product, weight-average molecular weight: 30,000) having the following structural formula was used in place of REB100-1.

The flexibility of the obtained resin sheet was favorable.

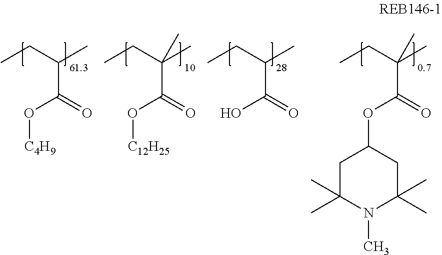

Next, a cured resin sheet was produced from the acrylic resin (REB146-1)-containing thermally conductive B-stage sheet in a similar manner to Example 1. The thermal conductivity of the obtained cured resin sheet was measured in a similar manner to Example 1 by a xenon flash method. The thermal conductivity was 10.3 W/mK.

Further, a heat dissipation device attached with the acrylic resin (REB146-1)-containing thermally conductive B-stage sheet was produced in a similar manner to Example 1.

The shear adhesive strength at 175° C. of the obtained heat dissipation device was measured in a similar manner to Example 1, and the result was 6.7 MPa.

The insulation was measured by a BDV method in a similar manner to Example 1, and the result was 3.2 kV/100 μm.

### Example 4

An acrylic resin (REB146-2)-containing thermally conductive B-stage sheet was produced as a resin sheet in a similar manner to Example 1, except that an acrylic elastomer REB146-2 (synthetic product, weight-average molecular weight: 50,000) having the following structural formula was used in place of REB100-1.

The flexibility of the obtained resin sheet was favorable.

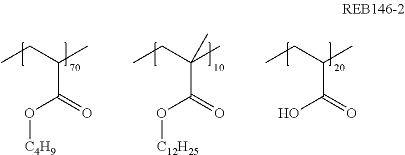

Next, a cured resin sheet was produced from the acrylic resin (REB 146-2)-containing thermally conductive B-stage sheet in a similar manner to Example 1.

The thermal conductivity of the obtained cured resin sheet was measured in a similar manner to Example 1 by a xenon flash method. The thermal conductivity was 10.6 W/mK.

Further, a heat dissipation device attached with the acrylic resin (REB 146-2)-containing thermally conductive B-stage sheet was produced in a similar manner to Example 1.

The shear adhesive strength at 175° C. of the obtained heat dissipation device was measured in a similar manner to Example 1, and the result was 5.0 MPa.

The insulation was measured by a BDV method in a similar manner to Example 1, and the result was 3.8 kV/100 μm.

### Example 5

An acrylic resin (REB100-2)-containing thermally conductive B-stage sheet was produced in a similar manner to Example 1, except that an acrylic elastomer REB100-2 (synthetic product, weight-average molecular weight: 98,000) having the following structural formula was used in place of REB100-1.

The flexibility of the obtained resin sheet was favorable.

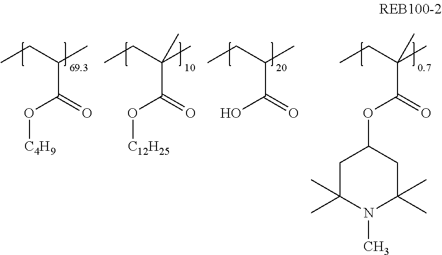

Next, a cured resin sheet was produced from the acrylic resin (REB100-2)-containing thermally conductive B-stage sheet in a similar manner to Example 1. The thermal conductivity of the obtained cured resin sheet was measured in a similar manner to Example 1 by a xenon flash method. The thermal conductivity was 10.5 W/mK.

Further, a heat dissipation device attached with the acrylic resin (REB100-2)-containing thermally conductive B-stage sheet was produced in a similar manner to Example 1.

The shear adhesive strength at 175° C. of the obtained heat dissipation device was measured in a similar manner to Example 1, and the result was 5.1 MPa.

The insulation was measured by a BDV method in a similar manner to Example 1, and the result was 3.8 kV/100 μm.

### Example 6

Into a 250-ml polyethylene bottle, 0.090 parts by mass of N-phenyl-3-aminopropyl trimethoxy silane (manufactured by Shin-Etsu Chemical Co., Ltd., trade name: KBM573), 0.5767 parts by mass of an acrylic elastomer REB122-4 (a synthetic product, weight-average molecular weight: 24,000) and 5.166 parts by mass of a cyclohexanon solution of a catechol resorcinol novolac (CRN) resin (solid content: 50 mass %) were placed in this order.

Next, after adding 150.00 parts by mass of alumina balls (size: 3 mm) to the polyethylene bottle, 12.19 parts by mass of aluminium oxide having a volume average particle size of 3 μm (manufactured by Sumitomo Chemical Company, Limited, alumina particles, AA-3) (content in the whole aluminium oxide: 70.6 vol %) and 5.08 parts by mass of aluminium oxide having a volume average particle size of 0.4 μm (manufactured by Sumitomo Chemical Company, Limited, alumina particles, AA-04) (content in the whole aluminium oxide: 29.4 vol %) were added. Further, 52.81 parts by mass of cyclohexanone was added, and mixed with a big rotor. After confirming that the mixture was uniform, 8.374 parts by mass of 1-{(3-methyl-4-oxiranylmethoxy)phenyl}-4-(4-oxiranylmethoxyphenyl)-1-cyclohexene, which was synthesized from 1-(3-methyl-4-hydroxyphenyl)-4-(4-hydroxyphenyl)-1-cyclohexene and epichlorohydrin by an ordinary method (epoxy resin), and 0.093 parts by mass of triphenylphosphine (manufactured by Wako Pure Chemical Industries, Ltd.) were added and further mixed. Then, a ball mill crushing treatment was performed for 40 hours to 60 hours. Thereafter, 40.29 parts by mass of boron nitride particles (volume average particle size: 40 μm, manufactured by MIZUSHIMA FERROALLOY CO., LTD., trade name: HP-40MF100, alumina particles:boron nitride particles=30 mass %:70 mass %) were added thereto, and a resin sheet coating liquid (resin composition) was obtained.

As a resin sheet, an acrylic resin (REB 122-4)-containing thermally conductive B-stage sheet was produced in a similar manner to Example 1.

The flexibility of the obtained resin sheet was favorable.

Next, a cured resin sheet was produced from the acrylic resin (REB 122-4)-containing thermally conductive B-stage sheet in a similar manner to Example 1. The thermal conductivity of the obtained cured resin sheet was measured in a similar manner to Example 1 by a xenon flash. The thermal conductivity was 11.2 W/mK.

Further, a heat dissipation device attached with the acrylic resin (REB122-4)-containing thermally conductive B-stage sheet was produced in a similar manner to Example 1.

The shear adhesive strength at 175° C. of the obtained heat dissipation device was measured in a similar manner to Example 1, and the result was 5.0 MPa.

The insulation was measured by a BDV method in a similar manner to Example 1, and the result was 4.0 kV/100 μm.

### Example 7

Into a 250-ml polyethylene bottle, 0.090 parts by mass of N-phenyl-3-aminopropyl trimethoxy silane (manufactured by Shin-Etsu Chemical Co., Ltd., trade name: KBM573), 0.5767 parts by mass of an acrylic elastomer REB122-4 (a synthetic product, weight-average molecular weight: 24,000) and 5.166 parts by mass of a cyclohexanone solution of a catechol resorcinol novolac (CRN) resin (solid content: 50 mass %) were added in this order.

Next, after adding 150.00 parts by mass of alumina balls (size: 3 mm) to the polyethylene bottle, 28.84 parts by mass of aluminium oxide having a volume average particle size of 3 μm (manufactured by Sumitomo Chemical Company, Limited, alumina particles, AA-3) (content in the whole aluminium oxide: 70.6 vol %) and 12.02 parts by mass of aluminium oxide having a volume average particle size of 0.4 μm (manufactured by Sumitomo Chemical Company, Limited, alumina particles, AA-04) (content in the whole aluminium oxide: 29.4 vol %) were added. Further, 52.81 parts by mass of cyclohexanone was added, and mixed with a big rotor. After confirming that the mixture was uniform, 8.374 parts by mass of 1-{(3-methyl-4-oxiranylmethoxy)phenyl}-4-(4-oxiranylmethoxyphenyl)-1-cyclohexene, which was synthesized by 1-(3-methyl-4-hydroxyphenyl)-4-(4-hydroxyphenyl)-1-cyclohexene and epichlorohydrin by an ordinary method (epoxy resin) and 0.093 parts by mass of triphenylphosphine (manufactured by Wako Pure Chemical Industries, Ltd.) were added and the mixture was further mixed. Then, a ball mill crushing treatment was performed for 40 hours to 60 hours. Thereafter, 27.24 parts by mass of boron nitride particles (volume average particle size: 40 μm, manufactured by MIZUSHIMA FERROALLOY CO., LTD., trade name: HP-40MF100, alumina particles:boron nitride particles=60 mass %:40 mass %) were added thereto, and a resin sheet coating liquid (resin composition) was obtained.

As a resin sheet, an acrylic resin (REB 122-4)-containing thermally conductive B-stage sheet was produced in a similar manner to Example 1.

The flexibility of the obtained resin sheet was favorable.

Next, a cured resin sheet was produced from the acrylic resin (REB 122-4)-containing thermally conductive B-stage sheet in a similar manner to Example 1. The thermal conductivity of the obtained cured resin sheet was measured in a similar manner to Example 1 by a xenon flash method. The thermal conductivity was 10.4 W/mK.

Further, a heat dissipation device attached with the acrylic resin (REB122-4)-containing thermally conductive B-stage sheet was produced in a similar manner to Example 1.

The shear adhesive strength at 175° C. of the obtained heat dissipation device was measured in a similar manner to Example 1, and the result was 5.8 MPa.

The insulation was measured by a BDV method in a similar manner to Example 1, and the result was 3.2 kV/100 μm.

### Comparative Example 1

### 1. Production of Non-Elastomer-Containing Thermally Conductive B-Stage Sheet

In a 250-ml polyethylene bottle, 0.090 parts by mass of N-phenyl-3-aminopropyl trimethoxy silane (manufactured by Shin-Etsu Chemical Co., Ltd., trade name: KBM573) and 5.438 parts by mass of a cyclohexanone solution of a catechol resorcinol novolac (CRN) resin (solid content: 50 mass %) as prepared in a similar manner to Example 1 were added in this order.

Next, after adding 150.00 parts by mass of alumina balls (size: 3 mm) in the polyethylene bottle, 21.64 parts by mass of aluminium oxide having a volume average particle size of 3 μm (AA-3) (manufactured by Sumitomo Chemical Company, Limited) and 9.02 parts by mass of aluminium oxide having a volume average particle size of 0.4 μm (AA-04) (manufactured by Sumitomo Chemical Company, Limited) were added. Further, 52.81 parts by mass of cyclohexanone were added, and mixed with a big rotor. After confirming that the mixture was uniform, 8.815 parts by mass of 1-{(3-methyl-4-oxiranylmethoxy)phenyl}-4-(4-oxiranylmethoxyphenyl)-1-cyclohexene, which was synthesized from 1-(3-methyl-4-hydroxyphenyl)-4-(4-hydroxyphenyl)-1-cyclohexene and epichlorohydrin by an ordinary method (epoxy resin), and 0.093 parts by mass of triphenylphosphine (manufactured by Wako Pure Chemical Industries, Ltd.) were added and the mixture was further mixed. Then, a ball mill crushing was performed for 40 hours to 60 hours. Thereafter, 32.89 parts by mass of boron nitride (volume average particle size: 40 μm, manufactured by MIZUSHIMA FERROALLOY CO., LTD., trade name: HP-40MF100) was added thereto, and a resin sheet coating liquid was obtained.

The obtained resin sheet coating liquid was applied onto a mold release surface of a polyethylene terephthalate film (75E-0010CTR-4, manufactured by FUJIMORI KOGYO CO., LTD., hereinafter, also simply referred to as a PET film) such that the thickness of the resin sheet coating liquid was about 400 μm, and left to stand in an ordinary state for 10 minutes. Thereafter, the film was dried in a box-type oven for 10 minutes, and a resin composition layer was formed on the PET film. A PET film having a resin composition layer was placed on another PET film having a resin composition layer such that the resin composition layers were in contact with each other, and a planarization treatment was performed by heat pressing (top heating plate: 150° C., bottom heating plate: 150° C., pressure: 15 MPa, treatment time: 4 minutes). A non-elastomer-containing thermally conductive B-stage sheet having a thickness of 250 μm was thus obtained as a resin sheet.

The flexibility of the obtained resin sheet was evaluated by a method as described below, and the result was not favorable.

### 2. Production of Cured Object of Non-Elastomer-Containing Thermally Conductive B-Stage Sheet

The PET films were peeled off from both sides of the non-elastomer-containing thermally conductive B-stage sheet obtained in the above-mentioned method, and the sheet was sandwiched by copper foils each having a thickness of 105 μm (GTS foil, manufactured by Furukawa Electric Co., Ltd.) and subjected to a vacuum heat pressing (top heating plate: 170° C., bottom heating plate: 170° C., degree of vacuum ≦1 kPa, pressure: 10 MPa, treatment time: 7 minutes). Then, the sheet was placed in a box-type oven and cured by performing step curing at 160° C. for 30 minutes and at 190° C. for 2 hours. From the obtained cured object sandwiched by copper foils, only copper was removed by etching with a sodium persulfate solution, and a cured object of the non-elastomer-containing thermally conductive B-stage sheet was obtained as a cured resin sheet.

The thermal conductivity of the obtained cured resin sheet was measured by a xenon flash method in a similar manner to Example 1, and the result was 10.5 W/mK.

### 3. Attachment of Non-Elastomer-Containing Thermally Conductive B-Stage Sheet to Metal Work

The PET films were peeled off from the non-acrylic resin-containing thermally conductive B-stage sheet obtained in the above method. The sheet was sandwiched by a copper plate and an aluminum plate, and subjected to a vacuum heat pressing (hot plate temperature: 140° C., degree of vacuum: ≦1 kPa, pressure: 0.2 MPa, treatment time: 10 minutes). Then, the sheet was placed in a box-type oven and cured by performing step curing at 140° C. for two hours, at 165° C. for 2 hours, and at 190° C. for 2 hours. A heat dissipation device was thus obtained.

The shear adhesive strength at 175° C. of the heat dissipation device attached with the non-elastomer-containing thermally conductive B-stage sheet was measured in a similar manner to Example 1. The result was 3.0 MPa.

The insulation was measured by a BDV method, and the result was 2.6 kV/100 μm.

### Comparative Example 2

An acrylic resin (REB100-3)-containing thermally conductive B-stage sheet was produced as a resin sheet in a similar manner to Example 1, except that an acrylic elastomer REB100-3 (synthetic product, weight-average molecular weight: 8,900) having the following structural formula was used in place of “REB100-1”.

The obtained resin sheet was hard, and the result of flexibility evaluation was not favorable.

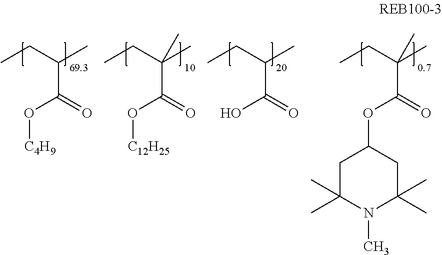

Next, a cured resin sheet was produced from the REB100-3-containing thermally conductive B-stage sheet in a similar manner to Example 1. The thermal conductivity of the obtained cured resin sheet was measured in a similar manner to Example 1 by a xenon flash method. The thermal conductivity was 10.3 W/mK.

Further, a heat dissipation device attached with the REB100-3-containing thermally conductive B-stage sheet was produced in a similar manner to Example 1.

The shear adhesive strength at 175° C. of the obtained heat dissipation device was measured in a similar manner to Example 1, and the result was 3.1 MPa.

The insulation was measured by a BDV method in a similar manner to Example 1, and the result was 2.3 kV/100 μm.

### Comparative Example 3

An acrylic resin (REB100-4)-containing thermally conductive B-stage sheet was produced as a resin sheet in a similar manner to Example 1, except that an acrylic elastomer REB100-4 (synthetic product, weight-average molecular weight: 110,000) having the following structural formula was used in place of REB100-1.

The obtained resin sheet was hard, and the result of flexibility evaluation was not favorable.

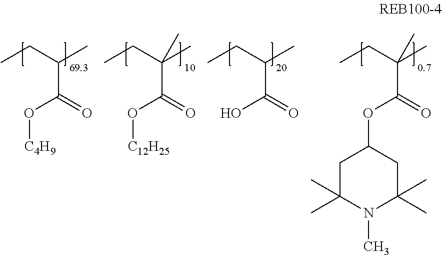

Next, a cured resin sheet was produced from the REB100-4-containing thermally conductive B-stage sheet in a similar manner to Example 1. The thermal conductivity of the obtained cured resin sheet was measured in a similar manner to Example 1 by a xenon flash method. The thermal conductivity was 10.1 W/mK.

Further, a heat dissipation device attached with the REB100-4-containing thermally conductive B-stage sheet was produced in a similar manner to Example 1.

The shear adhesive strength at 175° C. of the obtained heat dissipation device was measured in a similar manner to Example 1, and the result was 3.2 MPa.

The insulation was measured by a BDV method in a similar manner to Example 1, and the result was 2.0 kV/100 μm.

### Comparative Example 4

An HTR860P3-containing thermally conductive B-stage sheet was produced in a similar manner to Example 1, except that an acrylic elastomer HTR860P3 having a weight-average molecular weight of 800,000 (manufactured by Nagase ChemteX Corporation) in place of REB100-1.

The obtained resin sheet was hard, and the result of flexibility evaluation was not favorable.

Next, a cured resin sheet was produced from the HTR860P3-containing thermally conductive B-stage sheet in a similar manner to Example 1. The thermal conductivity of the obtained cured resin sheet was measured in a similar manner to Example 1 by a xenon flash method. The thermal conductivity was 10.7 W/mK.

Further, a heat dissipation device attached with the HTR860P3-containing thermally conductive B-stage sheet was produced in a similar manner to Example 1.

The shear adhesive strength at 175° C. of the obtained heat dissipation device was measured in a similar manner to Example 1, and the result was 3.8 MPa.

The insulation was measured by a BDV method in a similar manner to Example 1, and the result was 1.8 kV/100 μm.

TABLE 1

| | | | | | | | | | Com- | Com- | Com- | Com- |
|---|---|---|---|---|---|---|---|---|---|---|---|---|
| | | | | | | | | | par- | par- | par- | par- |
| | | | | | | | | | ative | ative | ative | ative |
| | | Exam- | Exam- | Exam- | Exam- | Exam- | Exam- | Exam- | Exam- | Exam- | Exam- | Exam- |
| | | ple 1 | ple 2 | ple 3 | ple 4 | ple 5 | ple 6 | ple 7 | ple 1 | ple 2 | ple 3 | ple 4 |
| Elas- | Type | REB100-1 | REB122-4 | REB146-1 | REB146-2 | REB100-2 | REB122-4 | REB122-4 | Not | REB100-3 | REB100-4 | HTR860P3 |
| tomer | | | | | | | | | in- | | | |
| | | | | | | | | | cluded | | | |
| | Weight- | 11,000 | 24,000 | 30,000 | 50,000 | 98,000 | 24,000 | 24,000 | — | 8,900 | 110,000 | 800,000 |
| | average | | | | | | | | | | | |
| | molecular | | | | | | | | | | | |
| | weight | | | | | | | | | | | |

| | | | | | | | | | | | |
|---|---|---|---|---|---|---|---|---|---|---|---|
| Resin | A | A | A | A | A | A | A | C | C | C | C |
| composition | | | | | | | | | | | |
| viscosity | | | | | | | | | | | |
| Insulation | 3.5 | 3.9 | 3.2 | 3.8 | 3.8 | 4.0 | 3.2 | 2.6 | 2.3 | 2.0 | 1.8 |
| property | | | | | | | | | | | |
| (kV)/100 μm | | | | | | | | | | | |
| Flexibility | A | A | A | A | B | A | A | C | C | C | C |
| Shear strength | 5.3 | 5.4 | 6.7 | 5.0 | 5.1 | 5.0 | 5.8 | 3.0 | 3.1 | 3.2 | 3.8 |
| (MPa) | | | | | | | | | | | |
| Thermal | 10.8 | 10.9 | 10.3 | 10.6 | 10.5 | 11.2 | 10.4 | 10.5 | 10.3 | 10.1 | 10.7 |
| conductivity | | | | | | | | | | | |
| (W/mK) | | | | | | | | | | | |

As shown in Table 1, the resin sheet formed by using the resin composition of the present invention exhibits an excellent flexibility. Further, the cured resin sheet formed by using the resin composition of the invention exhibits an excellent insulation and an excellent adhesion, in addition to an excellent thermal conductivity.

The disclosure of Japanese Patent Application No. 2011-196248 is incorporated in the present specification in its entirety.

All the documents, patent applications and technical standards described in the present specification are incorporated by reference in the present specification to the same extent as in cases where each document, patent application or technical standard is concretely and individually described to be incorporated by reference.

1. A resin composition, comprising:
a filler that includes alumina particles and boron nitride particles;
an elastomer having a weight-average molecular weight of from 10,000 to 100,000; and
a curable resin.

2. The resin composition according to claim 1, wherein the elastomer has a polarizable functional group.

3. The resin composition according to claim 2, wherein the functional group is at least one selected from the group consisting of an ester group, a carboxy group and a hydroxy group.

4. The resin composition according to claim 1, wherein the weight-average molecular weight of the elastomer is from 10,000 to 50,000.

5. The resin composition according to claim 1, wherein the content ratio of the alumina particles and the boron nitride particles in the filler (alumina particles:boron nitride particles) is 20 mass % to 80 mass %:80 mass % to 20 mass %.

6. A resin sheet that is a product formed by molding the resin composition according to claim 1 in a sheet shape.

7. A cured resin sheet that is a cured product of the resin sheet according to claim 6.

8. A heat dissipation device, comprising:
a metal work; and
the resin sheet according to claim 6, which is disposed on the metal work, the resin sheet being uncured or cured.

9. A resin-adhered metal foil, comprising:
a metal foil; and
a resin composition layer that is a coating of the resin composition according to claim 1, disposed on the metal foil.
